(19) United States
(12) Patent Application Publication
(10) Pub. No.: US 2001/0052631 A1
(43) Pub. Date: Dec. 20, 2001

(54) Semiconductor device having active area with angled portion

(76) Inventors: Yuji Takeuchi, Yokohama-shi (JP); Kazuhiro Shimizu, Yokohama-shi (JP); Riichiro Shirota, Fujisawa-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/794,089

(22) Filed: Feb. 28, 2001

(30) Foreign Application Priority Data
Feb. 28, 2000 (JP) 2000-051345

(51) Int. Cl. H01L 31/0328; H01L 31/0336; H01L 31/072; H01L 31/109; H01L 29/00

(52) U.S. Cl. 257/510

(57) ABSTRACT

The invention provides a semiconductor device having an active area with an angled portion. This semiconductor device comprises an active area having an angled portion, in which a semiconductor element is formed, and an isolation region formed adjacent to the active area. The angled portion of the active area includes first and second side walls and a third side wall formed in contact with the first and second side walls. A first angle between the first and third side walls and a second angle between the second and third side walls are obtuse angles.

### CROSS-REFERENCE TO RELATED APPLICATIONS

This application is based upon and claims the benefit of priority from the prior Japanese Patent Application No. 2000-051345, filed Feb. 28, 2000, the entire contents of which are incorporated herein by reference.

### BACKGROUND OF THE INVENTION

The present invention relates to a semiconductor device, and more particularly, to the configuration of an element area.

Referring to some of the figures, the background of the present invention will be described. FIG. 1 is a plan view illustrating a semiconductor element, more specifically, a resistance element. As is shown in FIG. 1, an isolation region 2 is formed around an active area 1 in which a semiconductor element is formed. The active area 1 has one end portion connected to wiring 4 with a contact 3 interposed therebetween, and the other end portion connected to wiring 6 with a contact 5 interposed therebetween. A diffusion layer (not shown), in which an impurity is implanted and diffused, is provided on the upper surface of the active area 1. This diffusion layer serves as a resistance element between wiring 4 and 6. Further, the active area 1 has a right-angled portion “C”.

A method for producing a semiconductor device having the semiconductor element shown in FIG. 1 will now be described.

FIGS. 2A, 3A, 4A, 5A and 6A are plan views, while FIGS. 2B, 3B, 4B, 5B and 6B are sectional views taken along respective lines A-B in FIGS. 2A-6A.

First, as shown in FIGS. 2A and 2B, an oxide film 9 and a mask material 10 are sequentially provided on a semiconductor substrate 8. Subsequently, the mask material 10 and the oxide film 9 are processed into a shape corresponding to the active area 1 having the angled portion “C”. Using the processed mask material 10 as a mask, the semiconductor substrate 8 is subjected to anisotropic etching, thereby forming a trench 7.

Thereafter, as shown in FIGS. 3A and 3B, an oxide is deposited on the semiconductor substrate 8 and the mask material 10, using CVD (Chemical Vapor Deposition), thereby forming an oxide film 11.

It should be noted that the oxide film 11 at and in the vicinity of the angled portion “C” has a different density to the other portions, for the reason described below.

When depositing silicon dioxide using CVD, a reaction seed (silane in this case) is supplied in the form of gas. As a result, the reaction seed chemically reacts with oxygen, thereby generating silicon dioxide. Silicon dioxide (corresponding to the oxide film 11) generated at a side wall “D” of the active area 1 uniformly sticks to the side wall “D”. On the other hand, it is possible that silicon dioxide (corresponding to the oxide film 11) generated at the angled portion “C” and its vicinities will stick to both side walls “E” and “F”of the active area 1. Further, the angled portion “C” is a narrow portion between the side walls “E” and “F” of the active area 1. In such a narrow portion, it is difficult for the reaction seed to enter. Accordingly, a desired amount of reaction seed cannot be supplied to it, and hence the density of the oxide film 11 is lower at the angled portion “C”.

After the execution of CVD for a certain period in time, the trench 7 is filled with the oxide film 11.

After that, as shown in FIGS. 5A and 5B, CMP (Chemical Mechanical Polishing) is executed until exposing the upper surface of the mask material 10, thereby removing part of the oxide film 11.

Subsequently, as shown in FIGS. 6A and 6B, wet etching is executed to thereby remove the mask material 10 and the oxide film 9. As well known, wet etching is a method for immersing a to-be-processed device in a predetermined liquid (etching liquid) to remove a to-be-removed film.

However, during the wet etching process, part of the oxide film 11 is removed at the angled portion “C”, since the density of the film 11 is lower at the angled portion “C” than at the other portions.

Thereafter, a diffusion layer serving as a resistance element, an interlayer insulating film, contacts 3 and 5 and wiring 4 and 6 are formed in this order, thereby completing the semiconductor device shown in FIG. 1.

As described above, when forming an insulator that constitutes the isolation region 2, i.e. the oxide film 11, around the active area 1 having the angled portion “C”, part of the oxide film 11 is inevitably removed at the angled portion “C” and its vicinities. If a conductive film is unintentionally filled in the removed portion, a semiconductor element formed in the active area 1 is electrically connected to a semiconductor element formed in another active area.

### BRIEF SUMMARY OF THE INVENTION

The present invention has been developed in light of the above-described circumstances, and aims to provide a highly reliable semiconductor device.

To satisfy the aim, the angled portion of an active area has a shape, which makes it difficult to remove an insulator that constitutes an isolation region.

For example, the angle between the side walls of the angled portion of the active area on the isolation region is made obtuse.

Alternatively, the angled portion of the active area is formed arcuate.

The thus-shaped angled portion of the active area makes it difficult to remove the insulator constituting the isolation region, and hence enables the provision of a highly reliable semiconductor device.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a plan view illustrating a semiconductor element formed in a conventional semiconductor device;

FIGS. 2A, 3A, 4A, 5A and 6A are plan views illustrating the procedure of producing the conventional semiconductor device;

FIGS. 2B, 3B, 4B, 5B and 6B are sectional views taken along respective lines A-B in FIGS. 2A-6A;

FIG. 7A is a plan view illustrating a semiconductor element formed in a semiconductor device according to a first embodiment of the invention;

FIG. 7B is a sectional view taken along line A-B in FIG. 7A;

FIGS. 8A, 9A, 10A, 11A and 12A are plan views illustrating the procedure of producing the semiconductor device of the first embodiment of the invention;

FIGS. 8B, 9B, 10B, 11B and 12B are sectional views taken along respective lines A-B in FIGS. 8A-12A;

FIG. 13A is a plan view illustrating a semiconductor device according to a first modification of the first embodiment of the invention;

FIG. 13B is a sectional view taken along line A-B in FIG. 13A;

FIG. 13C is a circuit diagram illustrating a circuit equivalent to that of the device shown in FIGS. 13A and 13B;

FIG. 14 is a plan view illustrating a semiconductor element formed in a semiconductor device according to a second modification of the first embodiment of the invention;

FIG. 15 is a plan view illustrating a semiconductor device according to a second embodiment of the invention;

FIG. 16 is an enlarged view illustrating the angled portion appearing in FIG. 15;

FIG. 17A is a plan view illustrating a semiconductor device according to a third embodiment of the invention;

FIG. 17B is a sectional view taken along line A-B in FIG. 17A;

FIG. 17C is a circuit diagram illustrating a circuit equivalent to that of the device shown in FIGS. 17A and 17B; and

FIG. 18 is a plan view illustrating a semiconductor device according to a modification of the third embodiment of the invention.

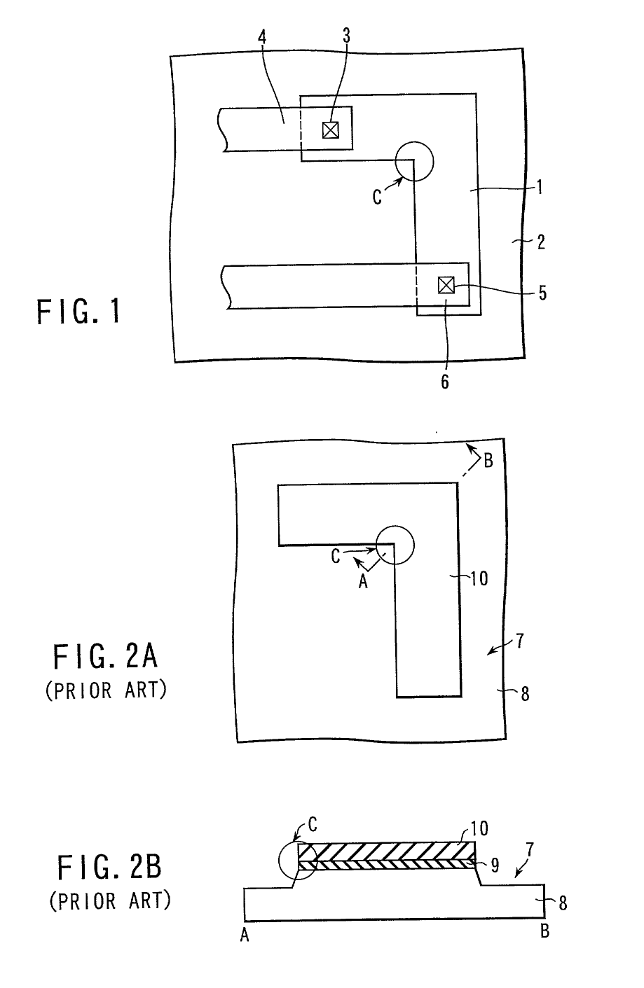

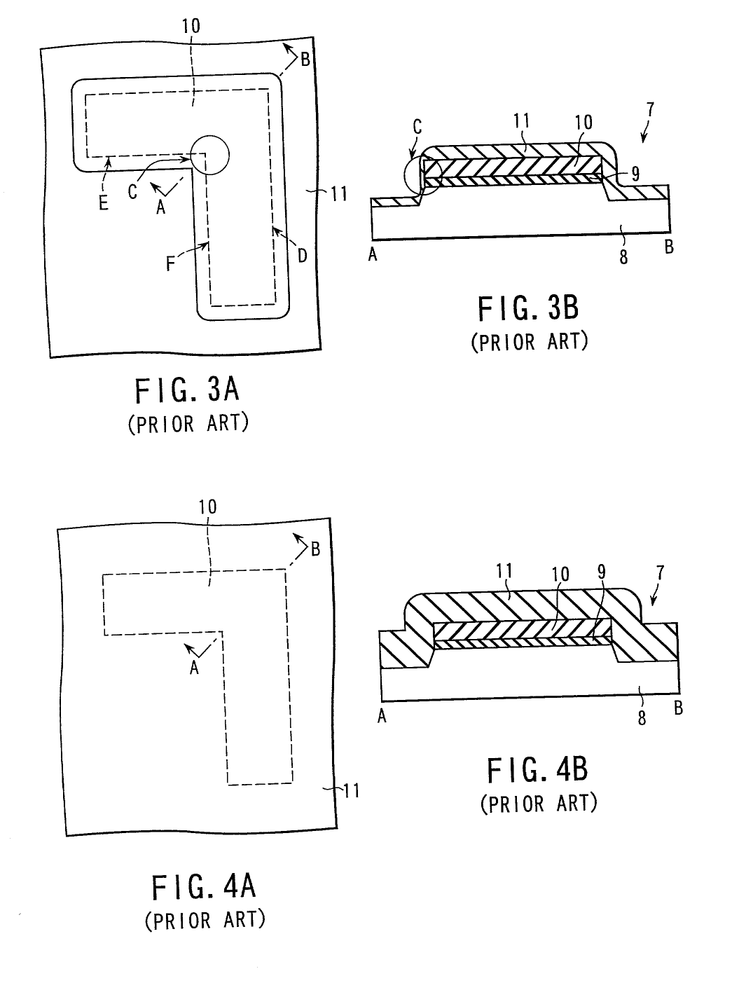

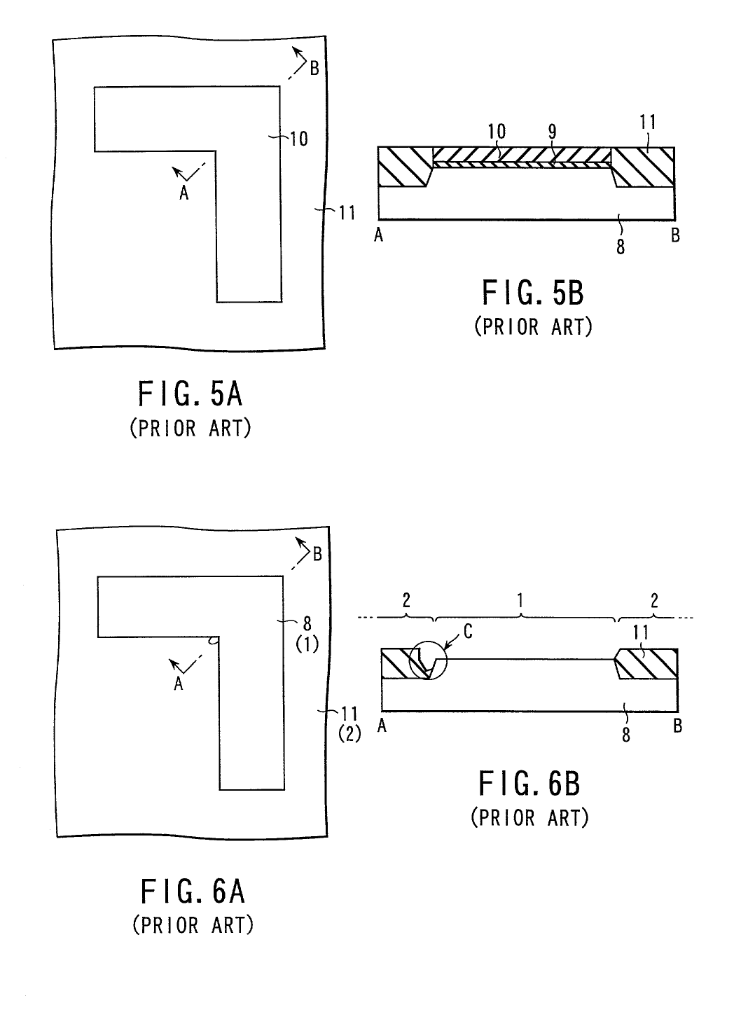

### DETAILED DESCRIPTION OF THE INVENTION

(First Embodiment)

A first embodiment of the invention will be described with reference to drawings relating thereto.

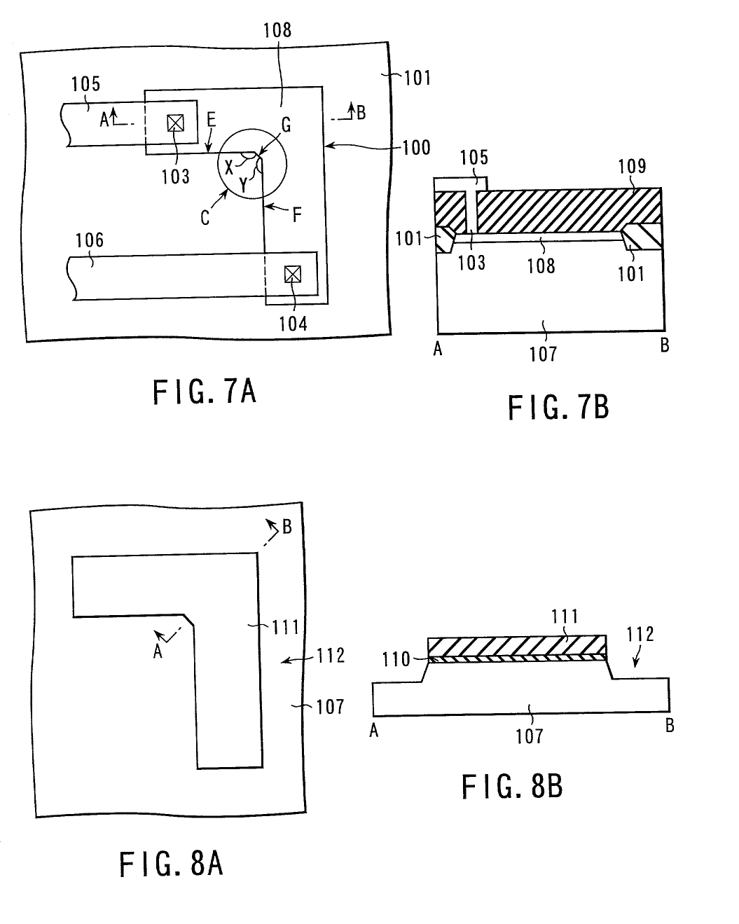

FIG. 7A is a plan view illustrating a semiconductor element, more particularly, a resistance element, formed in a semiconductor device according to the first embodiment of the invention. FIG. 7B is a sectional view taken along line A-B in FIG. 7A.

As shown in FIGS. 7A and 7B, an element isolation region 101 is formed around an active area 100 in which a semiconductor element is formed. The isolation region 101 electrically isolates a semiconductor element formed in the active area 100 from that formed in another active area. The region 101 is made of an insulator such as silicon dioxide. The active area 100 is formed of, for example, a P-type silicon substrate 107. An N-type diffusion layer 108 implanted with an N-type purity is formed in an upper surface portion of the active area 100. An interlayer insulating film 109 is formed on the active area 100 and the isolation region 101. Wiring 105 and 106 are formed on the interlayer film 109. The wiring 105 is electrically connected to one end of the active area 100, i.e. one end of the N-type diffusion layer 108, via a contact 103. Further, the wiring 106 is electrically connected to the other end of the N-type diffusion layer 108 via a contact 104. As a result, the N-type diffusion layer 108 serves as a resistance element between the wiring 105 and 106.

In the prior art, the angled portion “C” of the active area 1 is formed between the side walls “E” and “F” connected at right angles. In other words, the angled portion “C” consists of a right angle.

On the other hand, although the active area 100 in the embodiment also has an angled portion “C”, this angled portion is formed of side walls “E” and “F” and a side wall “G” provided therebetween in contact therewith. Accordingly, the angle “X” between the side walls “G” and “E” on the isolation region 101, and the angle “Y” between the side walls “G” and “F” on the isolation region 101 are obtuse angles larger than 90° and smaller than 180°.

A description will be given of a method for producing the semiconductor device according to the first embodiment.

FIGS. 8A, 9A, 10A, 11A and 12A are plan views illustrating the main procedure of producing the semiconductor device of the first embodiment. FIGS. 8B, 9B, 10B, 11B and 12B are sectional views taken along respective lines A-B in FIGS. 8A-12A.

At first, as shown in FIGS. 8A and 8B, an oxide film (e.g. a silicon dioxide film) 101 and a mask material (e.g. a silicon nitride film) 111 are sequentially layered on the upper surface of the P-type silicon substrate 107. Subsequently, the mask material 111 and the oxide film 110 are processed into a predetermined shape, in this embodiment, a shape corresponding to the active area 100 having the angled portion “C” with an obtuse angle “X” or “Y”. Using the processed mask material 111 as a mask, the P-type silicon substrate 107 is subjected to anisotropic etching by RIE, thereby forming a trench 112 therein.

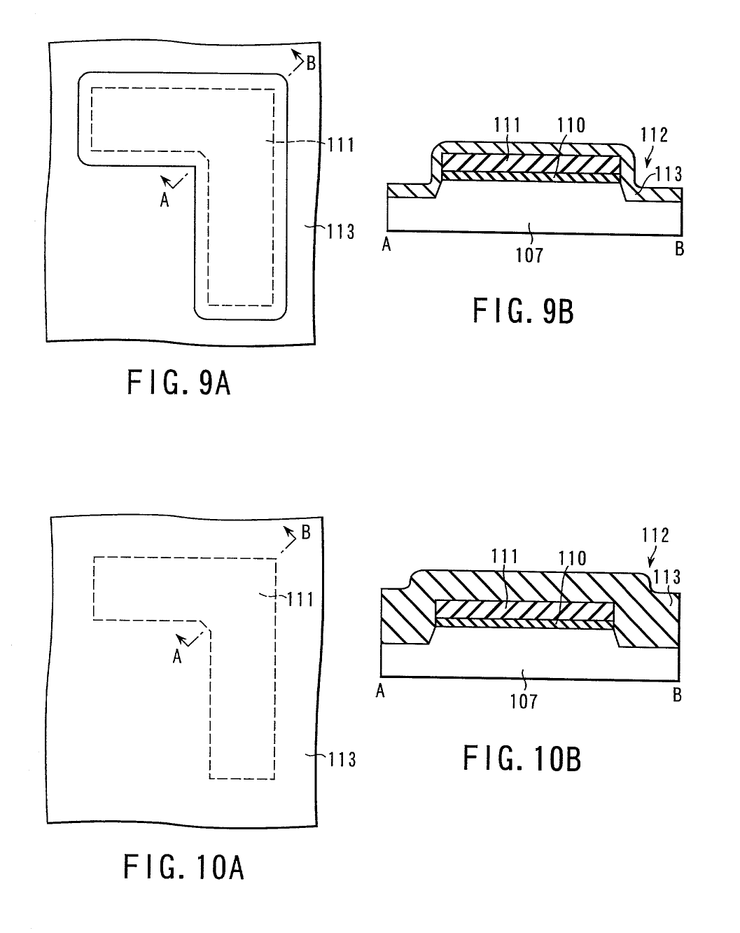

Thereafter, as shown in FIGS. 9A and 9B, an oxide (e.g. silicon dioxide) is deposited on the P-type silicon substrate 107 and the mask material 111 by CVD to form an oxide film 113 for filling the trench 112. The oxide film 113 is an insulator that constitutes the isolation region 101. After the execution of CVD for a certain period in time, an oxide film 113 of a thickness sufficient to fill the trench 112 is formed as shown in FIGS. 10A and 10B.

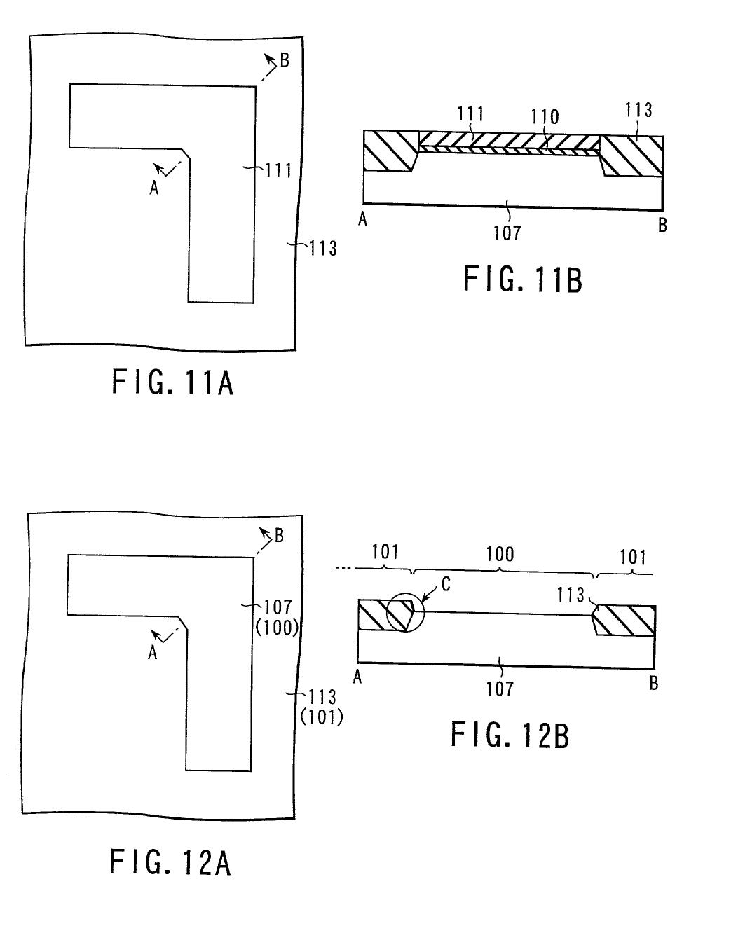

After that, as shown in FIGS. 11A and 11B, using the mask material 111 as a stopper, CMP is executed to polish the oxide film 113 to the same level as the upper surface of the mask material 111.

Subsequently, as shown in FIGS. 12A and 12B, wet etching is executed to thereby remove the mask material 111 and the oxide film 110.

During the wet etching process, even a small amount of the oxide film 113 is prevented from being removed at the angled portion “C” and its vicinities, for the reason mentioned later.

Thereafter, the N-type diffusion layer 108 serving as a resistance element, the interlayer insulating film 109, the contacts 103 and 104 and the wiring 105 and 106 are formed in this order, thereby completing the semiconductor device of the first embodiment shown in FIGS. 4A and 4B.

In the semiconductor device of the first embodiment constructed as above, the angled portion “C” of the active area 100 includes the side wall “G” provided between the side walls “E” and “F” in contact therewith as shown in FIG. 7A. Accordingly, the angle “X” between the side walls “G” and “E” on the isolation region 101, and the angle “Y” between the side walls “G” and “F” on the isolation region 101 are obtuse angles. This makes it easy to provide the angled portion with the oxide film 113 formed by CVD. Therefore, the density of the oxide film 113 is prevented from being reduced. This means that, during the wet etching process, even a small amount of the oxide film 113 is prevented from being removed at the angled portion “C”.

(First Modification of the First Embodiment)

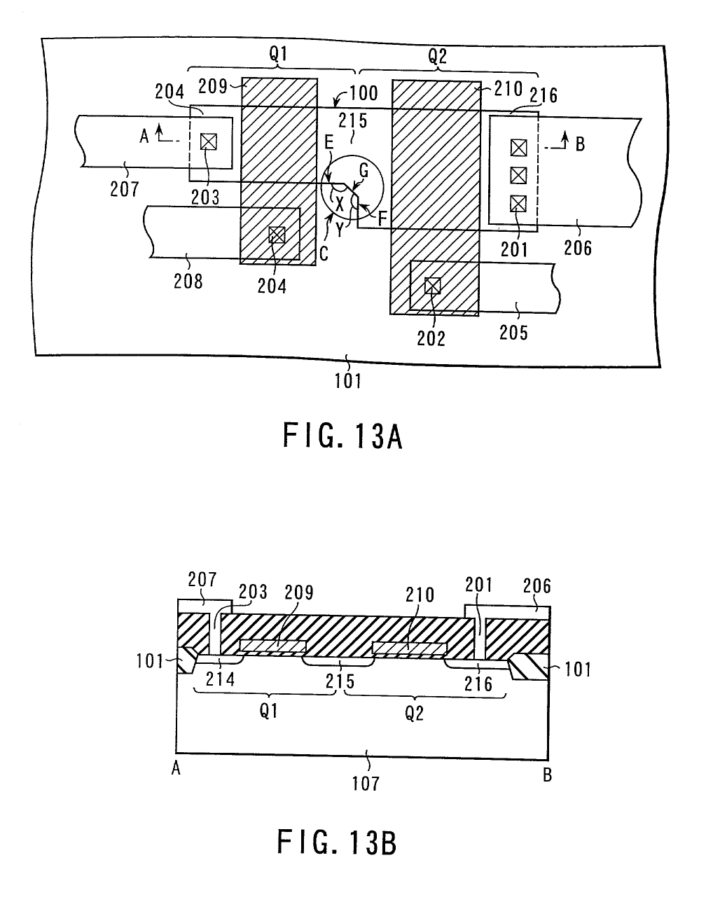

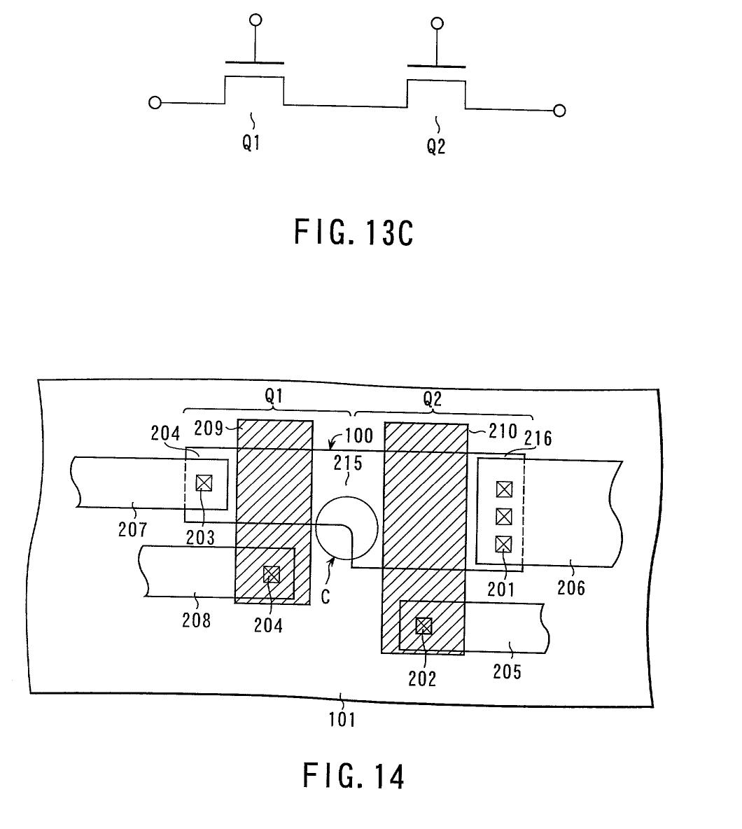

The first embodiment is directed to the basic structure of the invention. Referring now to FIGS. 13A-13C, a modification of the first embodiment will be described.

FIG. 13A is a plan view illustrating the first modification, FIG. 13B is a sectional view taken along line A-B in FIG. 13A, and FIG. 13C is a circuit diagram illustrating a circuit equivalent to that of the device shown in FIGS. 13A and 13B.

As shown in FIGS. 13A-13C, the active area 100 is connected to transistors Q1 and Q2 that are connected in series. The active area 100 has an angled portion “C”, either side of which the region 100 has different widths. The gate 209 of the transistor Q1 is formed such that it intersects the portion of the active area 100, which has a narrow width. The gate 210 of the transistor Q2 is formed such that it is separate from the gate electrode 209 by a predetermined distance and intersects the portion of the active area 100, which has a wide width. As a result, the channel width of the transistor Q1 differs from that of the transistor Q2. N-type source/drain diffusion layers 214, 215 and 216 are formed in those surface portions of the active area 100, on which the gate electrodes 209 and 210 are not provided.

Wiring 207 is connected to the N-type source/drain diffusion layer 214 via a contact 203, while wiring 206 is connected to the N-type source/drain diffusion layer 216 via a contact 201. Wiring 205 is connected to the gate electrode 210 via a contact 202, and wiring 208 is connected to the gate electrode 209 via a contact 204.

Also in the first modification, the angled portion “C” of the active area 100 includes the side wall “G” provided between the side walls “E” and “F” in contact therewith as shown in FIG. 13A. Accordingly, the angle “X” between the side walls “G” and “E” on the isolation region 101, and the angle “Y” between the side walls “G” and “F” on the isolation region 101 are obtuse angles.

Therefore, the first modification can provide the same advantage as the first embodiment.

(Second Modification of the First Embodiment)

FIG. 14 is a plan view showing a second modification of the first embodiment.

As shown in FIG. 14, in the second modification, the angled portion “C” of the active area 100 is curved and has a predetermined radius of curvature. The other structure of the second embodiment is similar to the first modification shown in FIG. 13A, and hence no detailed description is given thereof.

(Second Embodiment)

A second embodiment is directed to the application of the invention to a semiconductor memory device.

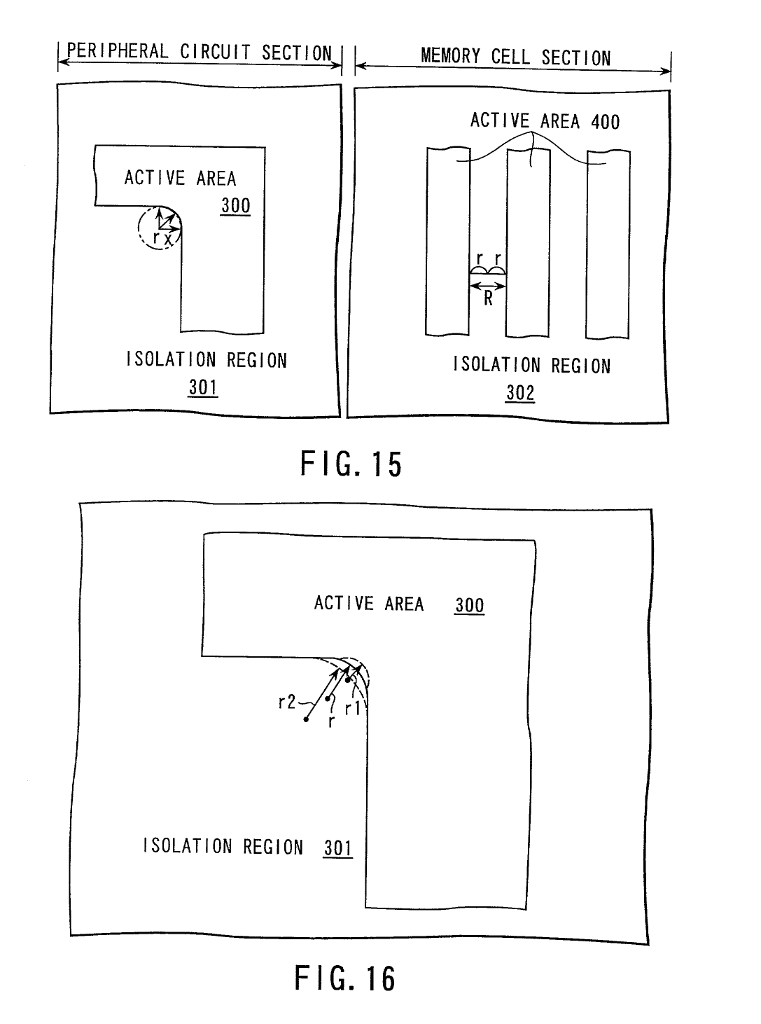

The second embodiment is shown in FIGS. 15 and 16. For facilitating the description, FIG. 15 shows only the active area and the isolation region of each of a memory cell section and a peripheral circuit section, and does not show any other elements.

The second embodiment is characterized in that the formula “rx>R/2” is established, where rx represents the radius of curvature of the angled portion “C” of an active area 300 in the peripheral circuit section, and R represents the width of an isolation region between adjacent active areas 400 in the memory cell section.

In the memory cell section shown in the right portion of FIG. 15, the active areas 400 formed of a semiconductor substrate such as a silicon substrate are arranged parallel to each other, and an isolation region 302 is formed around the active areas. In this case, the width of the isolation region 302 between the adjacent active areas 400 (the distance between the adjacent active areas) is represented by “R”, and the half length of “R” is represented by “r (=R/2)”.

In the peripheral circuit section shown in the left portion of FIG. 15, an isolation region 301 is formed around the active area 300 formed of a semiconductor substrate such as a silicon substrate. The radius of curvature of the angled portion “C” of the active area 300 is represented by “rx”.

Referring to FIG. 16, a description will be given of the relationship between the half length “r” of the width of the isolation region 302 between the adjacent active areas 400 in the memory cell section, and the radius-of-curvature “rx” of the angled portion “C” of the active area 300 in the peripheral circuit section. FIG. 16 is an enlarged view of the angled portion “C”.

In FIG. 16, the solid line indicates an angled portion “C” having a radius-of-curvature “r” equal to the aforementioned length “r”. The dotted chain line indicates an angled portion “C” having a radius-of-curvature “r1 (<r)” shorter than the length “r”. Further, the broken line indicates an angled portion “C” having a radius-of-curvature “r2 (>r)” longer than the length “r”.

As is also evident from FIG. 16, when the angled portion “C” has the radius-of-curvature “r1” shorter than the length “r”, it is difficult for a gaseous reaction seed to enter during CVD. This is because the side walls “E” and “F” are located close to each other and hence the route of entrance of the reaction seed is narrow. On the other hand, when the radius-of-curvature is equal to or longer (in the case of r2) than the length “r”, it is easy for the reaction seed to enter, since the side walls “E” and “F” are located not so close as in the first-mentioned case.

Moreover, the memory cell section occupies a greater part of the chip area of the semiconductor memory device. Therefore, if the area of the memory cell section is reduced, the required chip area is reduced. To reduce the area of the memory cell section, the distance “R” between the adjacent active areas 400 in the memory cell section is minimized in the chip. This means that an oxide film is provided in very narrow trenches in the isolation region 302 of the memory cell section.

In addition, the isolation region 301 of the peripheral circuit section and the isolation region 302 of the memory cell section are simultaneously provided with the oxide film. Accordingly, optimal gas conditions are selected for sufficiently coating the isolation region 302 which is expected to be most difficult to coat. In other words, whether or not a sufficient amount of oxide film is formed in the isolation region 301 of the peripheral circuit section depends upon the width “R” of the isolation region between the adjacent active areas in the memory cell section.

This will be described in more detail. In the memory cell section, if the width “R” of the isolation region 302 between the adjacent active areas 400 is narrowed, it is difficult for a reaction seed to enter the region. On the other hand, in the peripheral circuit section, if the angled portion “C” has a small radius of curvature, it is difficult for the reaction seed to enter the region. From these facts, it is understood to be desirable that the relationship “rx>R/2” should be satisfied, where rx represents the radius of curvature of the angled portion “C” in the peripheral circuit section, and r represents the half length (R/2) of the width of the isolation region 302 between the adjacent active areas 400 in the memory cell section.

Where the relationship “rx>R/2” is satisfied as described above, an oxide film of a sufficient thickness can be provided in both the memory cell section and the peripheral circuit section. Further, as in the first embodiment, even a small amount of the oxide film is prevented from being removed at the angled portion “C” during the wet etching process.

(Third Embodiment)

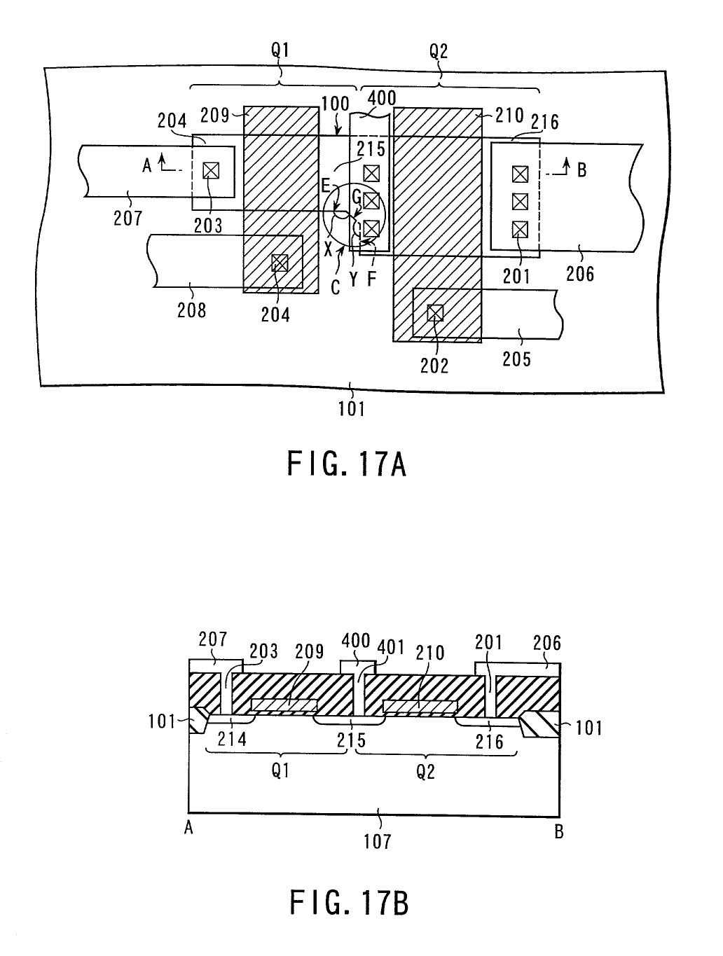

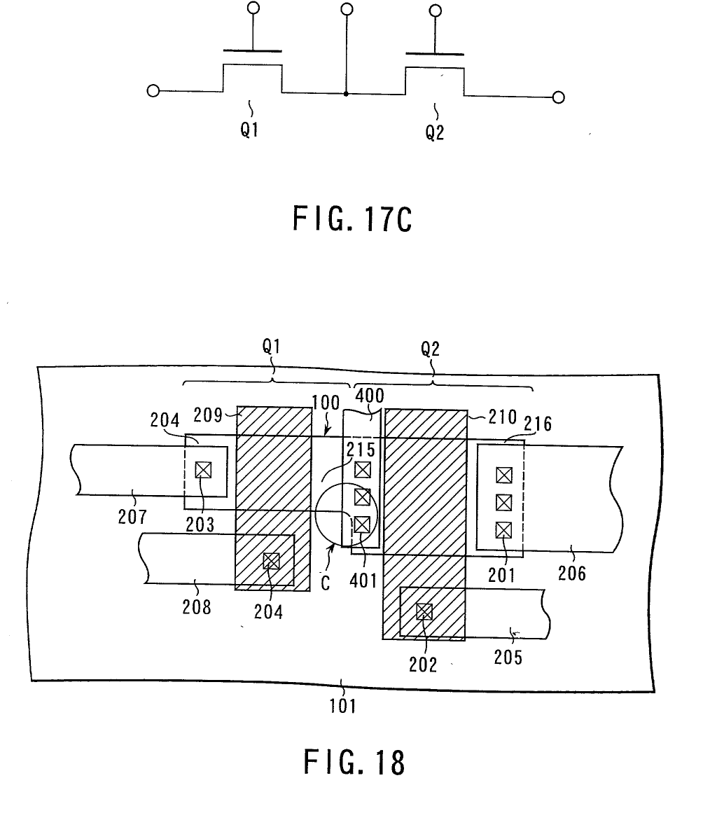

Referring to FIGS. 17A-17C, a third embodiment will be described.

FIG. 17A is a plan view illustrating a semiconductor device according to the third embodiment of the invention. FIG. 17B is a sectional view taken along line A-B in FIG. 17A. FIG. 17C is a circuit diagram illustrating a circuit equivalent to that of the device shown in FIGS. 17A and 17B.

As shown in FIGS. 17A-17C, the third embodiment differs from the first embodiment in that, in the former, wiring 400 is provided and connected to the N-type source/drain diffusion layer 215 via a contact 401. The other structures are similar to those of the first embodiment and hence not described.

Suppose that the angled portion “C” has an angle of 90° in the third embodiment. In this case, as described above, part of the oxide film is removed at the angled portion “C” and its vicinities. If, in a later process, a conductive film is unintentionally filled in the removed portion, electrically isolated elements may be electrically connected.

Moreover, if an N-type diffusion layer is formed in an upper surface portion of a P-type semiconductor substrate in an active area near the angled portion “C”, the P-type semiconductor substrate is electrically connected to the N-type diffusion layer via the unintentionally provided conductive film.

Also in the third embodiment, the angled portion “C” of the active area 100 includes the side wall “G” provided between the side walls “E” and “F” in contact therewith. Accordingly, the angle “X” between the side walls “G” and “E” on the isolation region 101, and the angle “Y” between the side walls “G” and “F” on the isolation region 101 are obtuse angles. Therefore, even if a voltage is applied to the N-type diffusion layer 215 adjacent to the angled portion “C”, the layer 215 is not electrically connected to any other semiconductor element. Thus, the invention is also effective in a structure in which a voltage is applied to the N-type diffusion layer 215 adjacent to the angled portion “C”.

In addition, since even a small amount of the isolation region 101 is prevented from being removed at the angled portion “C”, even when a diffusion layer of a predetermined conductivity type is formed in an upper surface portion of a semiconductor substrate of a conductivity type opposite to the first-mentioned one, the diffusion layer is prevented from being electrically connected to the substrate.

(Modification of the Third Embodiment)

FIG. 18 is a plan view illustrating a modification of the third embodiment.

As shown in FIG. 18, this modification differs from the third embodiment in that, in the former, the angled portion “C” of the active area 100 has an arcuate shape having a predetermined radius of curvature. The other structures are similar to those of the third embodiment and hence not described.

This structure can provide the same advantage as that obtained by the third embodiment.

Although the above-described first to third embodiments are directed to a structure in which an N-type diffusion layer is formed in a P-type semiconductor substrate, this may be modified such that a P-type diffusion layer is formed in an N-type semiconductor substrate.

Further, although, in the above-described first to third embodiments, the isolation region is formed around the active area, this may be modified such that the active area is formed around the isolation region.

Furthermore, although, in the above-described first to third embodiments, the active area is L-shaped when viewed as a plan view, the invention is not limited to this. For example, the active area may have a cross shape or a [symbol] or [symbol] shape, and it is sufficient if the active area has an angled portion.

As described above, the present invention, in which even a small amount of an insulator constituting the isolation region is prevented from being removed during the wet etching process, can provide a highly reliable semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an active area of a conductivity type, in which a semiconductor element is formed, the active area having an angled portion; and
an isolation region formed adjacent to the active area,
wherein the angled portion of the active area includes first and second side walls and a third side wall formed in contact with the first and second side walls, and a first angle between the first and third side walls and a second angle between the second and third side walls are obtuse angles.

2. The semiconductor device according to claim 1, wherein a diffusion layer of a conductivity type opposite to the first-mentioned conductivity type is formed in an upper surface portion of the active area having the angled portion.

3. The semiconductor device according to claim 2, wherein the diffusion layer of the conductivity type opposite to the first-mentioned conductivity type is connected to wiring for supplying the diffusion layer with a predetermined potential.

4. The semiconductor device according to claim 1, wherein the isolation region includes a trench formed adjacent to the active area, and an insulator filling the trench.

5. A semiconductor device comprising:
a memory cell section having first and second active areas in which memory cells are formed, and a first isolation region formed at least between the first and second active areas; and
a peripheral circuit section having a third active area of a conductivity type, and a second isolation region formed in contact with the third active area,
wherein the third active area has an arcuate angled portion having a predetermined radius of curvature; and
the predetermined radius of curvature is greater than a half value of a width of the first isolation region formed between the first and second active areas.

6. The semiconductor device according to claim 5, wherein a diffusion layer of a conductivity type opposite to the first-mentioned conductivity type is formed in an upper surface portion of the third active area having the arcuate angled portion.

7. The semiconductor device according to claim 6, wherein the diffusion layer of the conductivity type opposite to the first-mentioned conductivity type is connected to wiring for supplying the diffusion layer with a predetermined potential.

8. The semiconductor device according to claim 5, wherein the first isolation region includes a trench formed adjacent to the first and second active areas and filled with an insulator, and the second isolation region includes a trench formed adjacent to the third active area and filled with an insulator.

9. A semiconductor device comprising:
an active area in which a first transistor having a first channel width, and a second transistor having a second channel width differing from the first channel width are formed, the first and second transistor being connected in series, the first transistor having one of source/drain diffusion layers thereof connected to one of source/drain diffusion layers of the second transistor, the active area having an angled portion; and
an isolation region formed in contact with the active area,
wherein the angled portion of the active area includes first and second side walls and a third side wall formed in contact with the first and second side walls, and a first angle between the first and third side walls and a second angle between the second and third side walls are obtuse angles.

10. The semiconductor device according to claim 9, wherein the one of the source/drain diffusion layers, which is used by both the first and second transistors, is connected to wiring.

11. The semiconductor device according to claim 9, wherein the isolation region includes a trench formed adjacent to the active area, and an insulator filling the trench.

12. A semiconductor device comprising:
an active area in which a first transistor having a first channel width, and a second transistor having a second channel width differing from the first channel width are formed, the first and second transistor being connected in series, the first transistor having one of source/drain diffusion layers thereof connected to one of source/drain diffusion layers of the second transistor, the active area having an angled portion; and
an isolation region formed in contact with the active area,
wherein the angled portion of the active area is arcuate.

13. The semiconductor device according to claim 12, wherein the one of the source/drain diffusion layers, which is used by both the first and second transistors, is connected to wiring.

14. The semiconductor device according to claim 12, wherein the isolation region includes a trench formed adjacent to the active area, and an insulator filling the trench.
